(19) United States
(12) Patent Application Publication
(10) Pub. No.: US 2023/0036961 A1
(43) Pub. Date: Feb. 2, 2023

(54) MICROWAVE DEVICE

(71) Applicant: Metamaterial Inc., Dartmouth, CA (US)

(72) Inventors: Ragip Pala, Pleasanton, CA (US); Yaroslav Urzhumov, Issaquah, MA (US)

(21) Appl. No.: 17/443,100

(22) Filed: Jul. 20, 2021

(51) Int. Cl. H05B 6/76; H05K 9/00

(52) U.S. Cl. CPC H05B 6/766; H05K 9/0081

(57) ABSTRACT

A microwave device includes a microwave cavity, a frame, and a window having an electrically insulating substrate and a structure of metallic wires supported by the substrate. The frame defines a perimeter of an opening in the microwave cavity and the frame is conductive and grounded. The window spans the opening and is arranged to reflect RF radiation back into the cavity and to shield the outside of the microwave cavity from RF radiation. The window is optically transparent. Each metallic wire of the structure is electrically connected to the frame and the width of each metallic wire is between 100 nanometres and 30 micrometres.

### FIELD

The present disclosure relates to microwave devices, such as, but not limited to, microwave ovens. The present disclosure also relates to methods of manufacturing such devices or parts thereof.

### BACKGROUND

Electromagnetic interference (EMI), caused by electromagnetic signals interfering with each other, can affect the performance of electronic devices and may even result in damage to the human body. With increased use of electronic devices, there is an elevated density of EMI in the environment. EMI-induced damages and equipment malfunction, particularly in the microwave range, can be reduced by EMI shielding. One major challenge is realizing EMI shielding in optically transparent systems such as windows, while maintaining high optical transmittance.

Existing materials suitable for EMI shielding include Indium Tin Oxide (ITO), silver nanowires, graphene, carbon nanotubes or just simple metal meshes such as found on typical microwave oven doors, provide varying degrees of shielding effectiveness but have poor optical properties, e.g. low transparency and/or high haze.

### SUMMARY

According to an aspect of the present disclosure, there is provided a microwave device. The microwave device comprises a microwave cavity, a frame defining a perimeter of an opening in the microwave cavity, and a window spanning the opening. The frame is conductive and grounded. The window is arranged to reflect RF radiation back into the cavity and to shield the outside of the microwave cavity from RF radiation, and the window is optically transparent. The window comprises an electrically insulating substrate and a structure of metallic wires supported by the substrate. Each metallic wire of the structure is electrically connected to the frame, wherein the width of each metallic wire is between 100 nanometres and 30 micrometres.

The width of each metallic wire may be: between 100 nanometres and 10 micrometres; between 100 nanometres and 6 micrometres; between 100 nanometres and 2 micrometres; between 100 nanometres and 1 micrometre; between 100 nanometres and 0.5 micrometre; or between 100 nanometres and 0.1 micrometre. The width of each metallic wire may be approximately: 2 micrometres; 1 micrometre, 0.6 micrometre, 0.2 micrometre, or any other value in the above ranges. The metallic wires may have a rectangular cross-section, e.g. a square-cross section. The metallic wires may have a circular cross-section, or an elliptical cross-section. The width of one or more metallic wire may differ along the length of the metallic wire, e.g. either as a taper or stepwise. The thickness of each metallic wire may be between 100 nanometres and 30 micrometres.

By spanning the opening, the window fully occludes the opening such that there is no pathway for RF radiation to pass through the opening except through the window. In other words, there are no gaps between the window and the frame. The window may be formed as a single piece or comprise multiple pieces joined together. By being optically transparent, objects behind the window are clearly visible to the naked human eye. For example, the widths of the metallic wires are below the angular resolution of the unaided human eye at a distance away of 1 metre, approximately 30 micrometres. The widths of the metallic wires may be below the limit of resolution at closer distances, such as below 6 micrometres or below 2 micrometres, for example. Further, the optical transmittance of the window may be greater than 75%, greater than 90%, greater than 95%, or greater than 98%. The transmissive optical haze may be less than 10%, 5%, or 2%, wherein transmissive optical haze is defined as the optical power transmitted outside of a 2 degree cone with an axis normal to the surface of the transmissive surface, normalized to the total transmitted optical power, averaged over a selected band within the optical range of wavelengths. The window may have the above optical properties as explained above across any or all sub-ranges of optical frequencies, e.g. the visible spectrum, the near-infrared spectrum, or the mid-infrared spectrum.

To be arranged to reflect RF radiation back into the cavity and to shield the outside of the microwave cavity from RF radiation, the window may attenuate RF radiation by more than 20 dB, or by more than 40 dB. The shielding is a result of the high conductivity/low resistivity of the structure of metallic wires.

By being electrically connected to the frame, the metallic wires are electrically grounded, i.e. each part of the structure of metallic wires has a conductive pathway to ground via the frame. The conductive pathway may be via other metallic wires portions or by direct contact with the frame. This means the structure of metallic wires is uniformly, or substantially uniformly, electrically grounded. This provides high DC conductivity, i.e. low DC resistivity, at levels unachievable with short or discontinuous metal structures, e.g. randomly arranged nanowires or nanoparticle composites. Advantageously, this reduces the risk of gaps between conductors overcharging, in turn leading to electrostatic breakdown (arcing). This is particularly useful in high-power applications such as microwave ovens.

The microwave device may be a microwave oven. The microwave cavity may be a resonant cavity, which may have a Q-factor of greater than 10 or greater than 100. The microwave cavity may be a parallelepiped, e.g. a cuboid or an oblong. Alternatively, the microwave cavity could be substantially spheroid or cylindrical.

The substrate may be rigid, e.g. made from glass or sapphire. Alternatively, the substrate may be flexible, e.g. made from a polymer. Because the window is optically transparent, the substrate is transparent and may have any of the transparency properties as described above for the window as a whole. By being electrically insulating, the substrate has negligible conductivity compared to the metallic wires. The structure of metallic wires may be made, for example, from Silver, Aluminium, Platinum, Copper or Nickel.

The structure of metallic wires may be an array of metallic wire patterns, wherein the patterns either repeat or vary across the structure.

A microwave device as described herein has a higher window transparency than a comparative example of a microwave device window having the same effective shielding using Indium Tin Oxide (ITO), silver nanowires, graphene, carbon nanotubes, or metal meshes. Likewise, the microwave device has a higher window effective shielding than a comparative example of a microwave device window having the same transparency using Indium Tin Oxide (ITO), silver nanowires, graphene, carbon nanotubes, or metal meshes. A microwave device as described herein has a lower weight than a typical consumer microwave device using a metal mesh because the window has a lower proportion of metal.

The structure of metallic wires may be periodic, either in one or two dimensions. Such a periodic structure may be a rectangular or square array of a repeat pattern, or may be a triangular or hexagonal array of a repeat pattern. The period of such a periodic structure may be less than 500 micrometres. The period may be less than 200 micrometres.

As an alternative to a periodic structure, the structure of metallic wires may be aperiodic, such as an aperiodic rectangular array. The structure of metallic wires may be a rectangular grid of intersecting wires, e.g. a square grid. Accordingly, the structure may comprise a first plurality of metallic wires extending across the substrate in a first direction and a second plurality of metallic wires extending across the substrate in a second direction perpendicular to the first direction. Instead of a rectangular grid, the structure could be a parallelogram grid wherein the first and second directions are not perpendicular. Each end of each wire may connect the frame at opposite sides of the opening.

Each metallic wire of the structure may have an in-plane curvature, i.e. it curves across the surface of the substrate. Having curved wires, or wire portions, improves the optical performance of the window, by creating a more uniform scattering (diffraction) pattern. For example, the structure of metallic wires may comprise a plurality of wire portions wherein each wire portion is an arc. The arcs may be approximately a quarter of a circle. Each connection between adjacent wire portions is a T-junction, in other words, the point of connection between two adjacent wire portions is an end of one wire portion meeting an intermediate position of the other wire portion, wherein the adjacent wire portions are approximately perpendicular at the point of connection. This arrangement provides a particularly reliable production of a structuring having a uniform diffraction pattern, and a producing a particularly uniform diffraction pattern.

The total metallized area of the structure of metallic wires may be less than 20% of the area of the opening, or less than 10% of the opening, or less than 5% of the opening, or less than 1% of the opening. The metallized area of the structure does not include the areas bound between wires, e.g. the square or rectangles of a grid. This parameter is sometimes called the fill-factor (alternatively one minus the aperture ratio expressed as a percentage). Since metal is generally not transparent for optical frequencies, reducing the fill-factor increases the transparency.

The window may further comprise a secondary layer in a plane substantially parallel to the structure of metallic wires, wherein the second layer is arranged to reflect RF radiation back into the cavity and to shield the outside of the microwave cavity from RF radiation. The secondary layer may comprise a transparent conductive oxide. Alternatively, the secondary layer may be a second structure of second metallic wires, wherein each second metallic wire of the second structure is electrically connected to the frame, wherein the width of each second metallic wire is between 100 nanometres and 30 micrometres. The second structure of second metallic wires may have any of the features as described for the (first) structure of metallic wires and may have the same characteristics of the first structure or different characteristics. For example, each second metallic wire of the second structure may be electrically connected to the frame, or may be electrically connected to a second frame that is conductive and grounded.

The secondary layer may be separated from the first structure, in a direction perpendicular to the plane, by between 0.08 and 0.42 times the effective wavelength of an operating frequency of the microwave device. The separation may be 0.25 times the effective wavelength of an operating frequency. The effective wavelength of an operating frequency is defined as the wavelength of that frequency in the medium between the secondary layer and the first structure (i.e. the first layer), which is generally the free space wavelength scaled down by a factor of the refractive index of the medium.

The secondary layer may be supported by the same substrate as the first layer, i.e. the first structure of metallic wires. Alternatively, the secondary layer may comprise a second substrate on which the shielding components such as the second structure are supported.

In addition to the secondary layer, there may be further layers arranged to reflect RF radiation back into the cavity and to shield the outside of the microwave cavity from RF radiation, and the same principles apply to further layers and separation(s) therebetween as the secondary layer as described above.

The window may have on ore more of the following properties or sets of properties: RF reflectance greater than 99%; RF absorbance of less than 1%; RF reflectance greater than 99% and RF absorbance of less than 1%; RF attenuation greater than 20 dB; RF attenuation greater than 40 dB; DC sheet resistance of the structure of metallic wires less than 2 Ohm per square and RF sheet resistance the structure of metallic wires less than 2 Ohm per square; optical transparency greater than 75%, DC sheet resistance of the structure of metallic wires less than 2 Ohm per square, and RF sheet resistance the structure of metallic wires less than 2 Ohm per square; DC sheet resistance of the structure of metallic wires less than 5 Ohm per square and RF sheet resistance the structure of metallic wires less than 5 Ohm per square; optical transparency greater than 90%, DC sheet resistance of the structure of metallic wires less than 5 Ohm per square, and RF sheet resistance the structure of metallic wires less than 5 Ohm per square; DC sheet resistance of the structure of metallic wires less than 100 Ohm per square and RF sheet resistance the structure of metallic wires less than 100 Ohm per square; optical transparency greater than 98%, DC sheet resistance of the structure of metallic wires less than 100 Ohm per square, and RF sheet resistance the structure of metallic wires less than 100 Ohm per square; transmissive optical haze less than 10%; transmissive optical haze less than 5%; and transmissive optical haze less than 2%. Accordingly, the window can achieve combinations of high transparency coupled with low DC sheet resistance hitherto unobtainable. These properties can have many advantages, for example in microwave ovens, since high shielding of RF radiation can be achieved for a substantially transparent door window. This means the contents of the microwave oven can be seen more clearly by a user during operation.

The microwave device may comprise a door of the microwave cavity, wherein the door comprises the frame and the window. Accordingly, a door with transparent shielding is produced to provide a clearer view to a user regarding the contents of the cavity.

The microwave device may comprise a source of RF radiation arranged to emit RF radiation at an operating frequency into the microwave cavity, wherein the window is arranged to reflect RF radiation back into the cavity at the first wavelength and to shield the outside of the microwave cavity from RF radiation at the operating frequency. In examples, where there is a secondary layer separated from the first structure, this operating frequency defines the separation as explained above. The operating frequency may be in the range 300 MHz-300 GHz. The operating frequency may be within any ISM band within the range 300 MHz-300 GHz. The operating frequency may be in the 2.45 GHz ISM band, wherein the 2.45 GHz ISM band comprises the 2.4-2.5 GHz band. The operating frequency may be adjusted to any value within the 2.4-2.5 GHz band. The operational frequency may be adjusted to any value within the 300 MHz-300 GHz range.

The microwave device may comprise a plurality of frames including the (first) frame and a plurality of windows including the (first) window. Each frame defines a perimeter of a respective opening of the microwave cavity, wherein each frame is conductive and grounded, and each window spans the respective opening of a respective frame. In this example, each window comprises an electrically insulating substrate and a structure of metallic wires supported by the respective substrate, wherein each metallic wire of the structure is electrically connected to the respective frame, wherein the width of each metallic wire is between 100 nanometres and 30 micrometres. The plurality of frames may collectively cover the majority of the surface area of the microwave cavity. For example, there may be 2, 3, 4, 5, or 6 frames each arranged on a respective face of a cuboid microwave cavity. With the corresponding windows in each frame, this means the content of the microwave cavity can be viewed from multiple angles, through multiple walls of the cavity (or even above or below).

The microwave device may comprise an infrared source, wherein the window is substantially transparent in the infrared spectrum and the window is positioned between the infrared source and the microwave cavity. As such, infrared radiation can enter the microwave cavity, e.g. in order to heat the contents or image the contents, but RF radiation is not transmitted back out of the microwave cavity.

According to an aspect of the present disclosure, there is provided a method of manufacturing a screen for shielding RF radiation. The method comprises producing a pattern on a photosensitive material and depositing a structure of metallic wires on the photosensitive material according to the pattern, wherein the width of each metallic wire is between 100 nanometres and 30 micrometres. The method comprises attaching a window to a frame, wherein the frame defines a perimeter of an opening, such that the window spans the opening, wherein the window is optically transparent. The window comprises an electrically insulating substrate and the periodic structure of metallic wires supported by the substrate. The method comprises electrically connecting each metallic wire to the frame.

The method may comprise transferring the metallic wires from the photosensitive material onto the substrate. Alternatively, the photosensitive material may itself be the substrate, or part of the substrate, or supported by the substrate. Producing the pattern on the photosensitive material may be using a mask, e.g. using Rolling Mask Lithography®. The producing a pattern and depositing the structure of metallic wires may be performed before or after the attaching the window to the frame.

The electrically connecting each metallic wire to the frame may be part of the depositing the structure of metallic wires on the photosensitive material, for example, if the pattern extends to contact the frame or extends onto the frame itself. Alternatively, the electrically connecting each metallic wire to the frame may include disposing a conductive bridge between the frame and the structure of metallic wires at one or more positions around the structure of metallic wires. As already discussed, the electrically connecting each metallic wire to the frame may be achieved by electrically connecting one or more peripheral portions of metallic wires to the frame, wherein the structure of the metallic wires is such that substantially the entire structure of metallic wires is electrically connected to the frame, with some portions connected via other portions.

According to an aspect of the present disclosure, there is provided a screen for shielding RF radiation, comprising a frame defining a perimeter of an opening and a window spanning the opening. The frame is conductive and grounded. The window and electrically insulating substrate and a structure of metallic wires supported by the substrate. Each metallic wire of the structure is electrically connected to the frame and the width of each metallic wire is between 100 nanometres and 30 micrometres.

The frame and window, and substrate and structure of the window, may have any of the features as described above for the corresponding components of the microwave device.

According to an aspect of the present disclosure, there is provided a multifunctional microwave metamaterial layer arranged to be reflective and attenuating to microwave radiation and simultaneously transparent to optical radiation. The metamaterial layer comprises an electrically insulating, optically transparent substrate and a structured array of metallic wire patterns supported by the substrate. Each metallic wire in each pattern of the array is electrically connected to at least one point on the periphery of the layer, wherein the width of each metallic wire is between 100 nanometres and 30 micrometres.

The DC sheet resistance averaged over any sub-area of the metamaterial layer may be less than 2 Ohm per square, and the optical transparency may be greater than 75%. The DC sheet resistance averaged over any sub-area of the metamaterial layer may be less than 5 Ohm per square, and the optical transparency may be greater than 90%. The DC sheet resistance averaged over any sub-area of the metamaterial layer may be less than 100 Ohm per square, and the optical transparency may be greater than 98%. The metamaterial layer may be arranged to have transmissive optical haze less than 10%, 5%, or 2%.

According to the aspects described herein and set out in the appended claims, higher levels of electromagnetic radiation shielding effectiveness are achieved without compromising optical properties and vice versa.

### BRIEF DESCRIPTION OF THE FIGURES

The patent or application file contains at least one drawing executed in color. Copies of this patent or patent application publication with color drawing(s) will be provided by the Office upon request and payment of the necessary fee.

Specific embodiments are now described by way of example and with reference to the accompanying drawings, in which:

FIG. 1 shows a microwave device;

FIG. 2 shows a frame and window of a microwave device and a zoomed-in portion of a periodic structure of metallic wires;

FIG. 3 shows a portion of a periodic structure of metallic wires;

FIGS. 4a and 4b show graphs of results;

FIG. 5 shows a portion of a periodic structure of metallic wires;

FIG. 6 shows a diffraction plot for a periodic structure as shown in FIG. 3;

FIG. 7 shows a diffraction plot for a periodic structure as shown in FIG. 5;

FIG. 8 shows two periodic structures of metallic wires;

FIG. 9 shows an attenuation versus separation plot;

FIG. 10 shows a method of manufacturing a screen for shielding RF radiation; and

FIG. 11 shows a graph of transparency versus sheet resistance for various types of RF shielding.

### DETAILED DESCRIPTION

In overview, microwave devices for processing items using microwave radiation have various uses. Some microwave devices are microwave ovens, such as consumer microwave ovens or commercial kitchen microwave ovens for cooking food, others are used for heating or drying other types of objects such as clothing. Other microwave devices include lab devices for testing samples under microwave radiation. In any of these examples, it is important for microwave radiation not to escape the microwave cavity, since this could cause harm to nearby objects or people. For typical consumer microwave ovens this is done using a metal mesh, wherein the holes and spacing between holes are just less than or close to the wavelength of microwave radiation, i.e. around 1 millimetre to 1 centimetre. This has a similar effect to a conductive sheet (since the holes in the mesh are sub-wavelength) which provides shielding against the microwave radiation, e.g. reflects. The holes provide some visibility into the microwave cavity for a user to gain a limited view of the contents during processing. In contrast, the microwave devices as described herein have higher effective shielding, improved optical properties, or both.

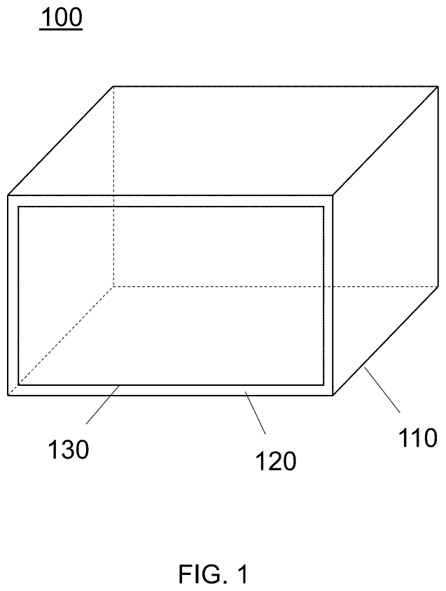

With reference to FIG. 1, a microwave device 100 comprises a microwave cavity 110, a box comprising six sides enclosing a region in which objects to be processed with microwave radiation is placed. One side of the microwave cavity has a frame 120, in this case a rectangular frame forming a border of the side of the cavity. The frame attaches to the other sides of the cavity, e.g. by a hinge. The frame has an opening in an interior portion through which the contents of the microwave cavity 110 can be seen. In order to shield the viewer from microwave radiation in operation, the opening is covered by a window 130 which is both transparent and shields microwave radiation.

Apart from the frame and window as disclosed herein, the form and properties of the microwave device and its components may be according to any conventional technology for microwave devices, e.g. turntables, user interfaces, processors for controlling radiation application, etc. A source of microwave radiation (not shown) may be part of the microwave or, alternatively, could be external with the produced radiation produced being directed into the microwave device via waveguides. The microwave cavity walls in general are made from metal and the frame can be made from metal. Alternative materials are possible as well, provided that the frame is conductive. The frame is also grounded. Being grounded means that, the frame is arranged such that, in use, there is a relatively low resistance electrical pathway from the frame to the earth. For example, this may be through the feet of the microwave device, through a plug socket, etc.

In alternative arrangements, the microwave device may have multiple frames on a single side of the microwave cavity, e.g. defining several openings for viewing, or there may be one or more frames on multiple sides of the microwave cavity 110.

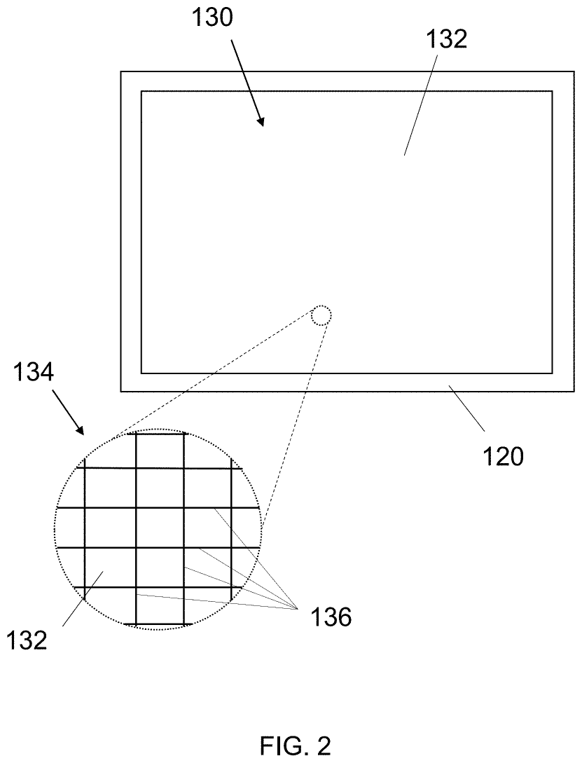

With reference to FIG. 2, the frame 120 and window 130 will be described in further detail. The window 130 comprises a substrate 132 supporting a structure 134 of metallic wires 136. The width of the metallic wires is below the level of resolution for an unaided human eye at a distance of approximately 1 metre away, which is a typical distance from within which a user might be viewing inside the microwave cavity. Further, the substrate 132 of the window 130 is transparent and so the window as a whole does not inhibit the user's view into the microwave cavity 110.

As shown in the zoomed-in portion to FIG. 2 (which is not to scale), in an example the structure 134 takes the form of a rectangular grid, with rows and columns of metallic wires 136 intersecting at the grid points.

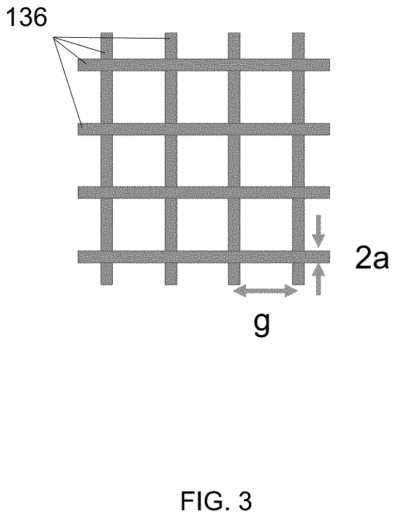

With reference to FIG. 3, showing a portion of a structure of metallic wires in the form of a grid, the width of the metallic wires is denoted ‘2a’ (wherein ‘a’ is half-width). The period between two columns or rows of the grid is denoted ‘g’. With these parameters, an analytical model for the transmission of the structure of metallic wires is:

$$T ≅ {\frac{4 {g}^{2}}{{λ}^{2}} [ ln ( sin \frac{π a}{g} ) ]}^{2} \qquad ( 1 )$$

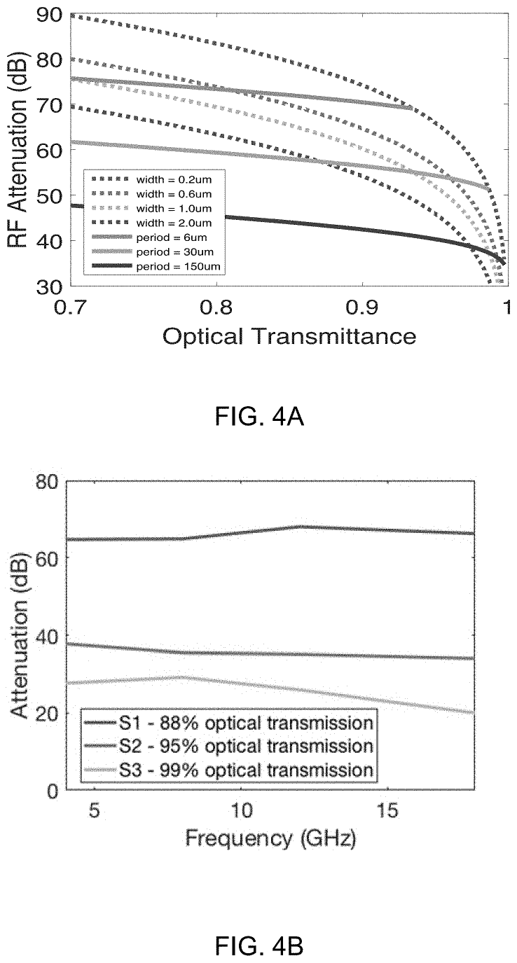

With reference to FIG. 4, the relationships between width and period with RF attenuation and optical transmittance are plotted. FIG. 4A illustrates RF Attenuation at 3 GHz vs. Optical transmittance for a selection of metallic wire widths and periods. Optical transmission is varied by keeping one wire parameter constant, i.e. width or period, while varying the other parameter to produce a plotted line. The dotted lines (from top to bottom of the graph) are for a width of 0.2 μm, 0.6 μm, 1.0 μm and 2.0 μm. The solid lines (from top to bottom) are for a period of 6 μm, 30 μm, and 150 μm. Optical transmittance can be determined by the fill factor (metallized area divided by the total area of the window), or conversely by aperture ratio (open area divided total area). At any transmittance value, smaller wire width enables higher EMI shielding. For this calculation it is assumed that the wires are thicker than the skin depth (e.g. approximately 1 μm at 3 GHz frequency).

EMI shielding increases with smaller linewidths for the same fill factor of the structure of metallic wires, while the fill factor determines the transparency of the window. Therefore, using metallic wires with less than 30 μm, and even more so for sub-micron widths, significantly improves the shielding effectiveness compared to conventional microwave shielding.

FIG. 4B shows the measured shielding effectiveness (microwave attenuation in dB) for two designs of the structure of metallic wires, across a range of frequencies from 5 to 20 GHz. A high shielding (60-70 dB attenuation) is achieved without sacrificing optical transparency (˜90%+ optical transmission).

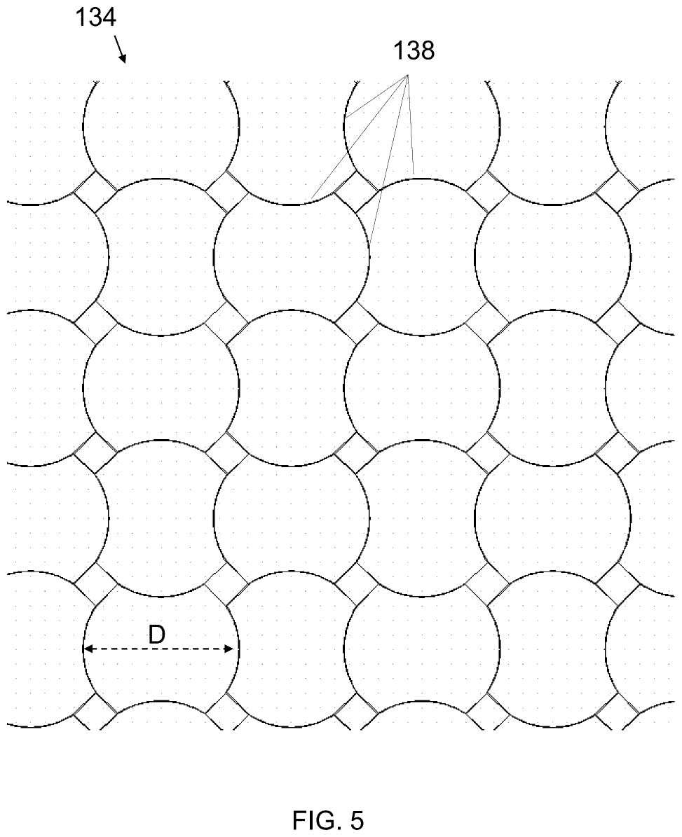

With reference to FIG. 5, as an alternative to a rectangular grid, a structure of metallic wires has curvature in the plane of the substrate. FIG. 5 is a zoomed-in birds-eye view of the surface of the window 130. In the example arrangement as shown in FIG. 5, the structure 134 of metallic wires is made up of a number of wire portions 138, each of which are curved approximately in the shape of an arc of a circle, approximately a quarter circle. The ends of each wire portion (except for at the edge of the structure) join an adjacent wire portion at an intermediate position of the adjacent wire. The join is a T-junction, i.e. the end of one wire portion meets the other wire portion perpendicularly. The intermediate position of the adjacent wire portion is at approximately a fifth or a quarter of the length along the wire portion. More generally, the intermediate position may be in a third of the wire portion length towards either end of the wire portion. The reliability of connection between wire portions, and so the metallic wires being connected across the structure is improved by using T-junctions compared to having wire portions cross over each other in an X shape. This is because, for a T-junction, no position of the metallic wire is further than a half-width away from the edge of the metallic wire. By comparison, for wires crossing perpendicularly (in an X shape), the mid-point of the cross is a distance away from the edge of the metallic wire of the square root of 2 (approximately 1.41) times the half-width of the metallic wires. In some circumstances, this results in a break in the continuity of the metallic wires due to the fabrication process which is designed to deposit metal of the normal width of the wire. In turn, breaks in the structure of metallic wires may compromise the high DC conductivity, and low DC resistivity, of the structure. A characteristic dimension of the structure 134 is the distance between the concave sides of wire portions which face each other, denoted as ‘D’. This is approximately half of the period of the structure 134.

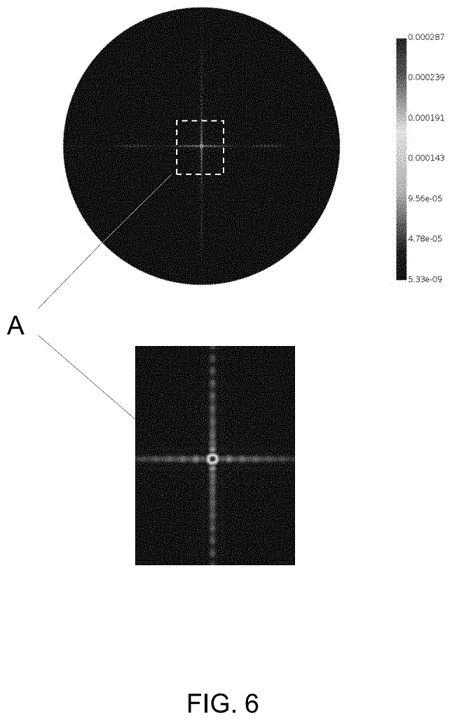

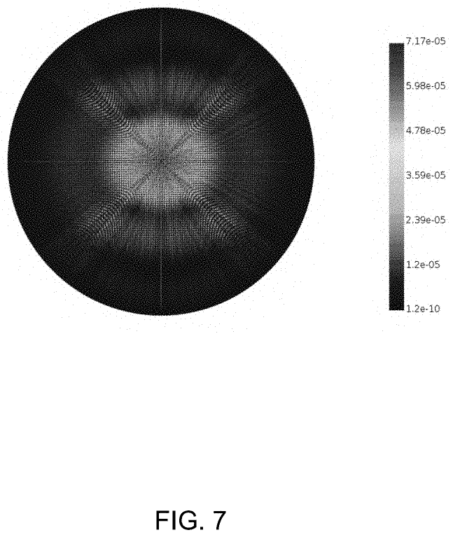

With reference to FIGS. 6 and 7, a structure wherein the metallic wires have in-plane curvature improves the optical performance of the window 130 compared to metallic wires in a grid. FIG. 6 shows a polar plot of the diffraction pattern from a grid of metallic wires and shows a zoomed-in portion A of the central part of the diffraction pattern. The diffraction pattern exhibits a strong signature at the centre and along two directions corresponding to the rows and columns of the grid. FIG. 7 also shows a polar plot of a diffraction pattern, except for a structure of metallic wires having in-plane curvature, e.g. curved wire portions. The diffraction pattern is more even than the diffraction pattern in FIG. 6, and the peak value is lower. This more even diffraction pattern reduces the visual impact of the window, providing better optical properties for viewing the contents of the microwave cavity. Accordingly, by choosing curved metallic wires, the optical properties of the window 130 are further improved.

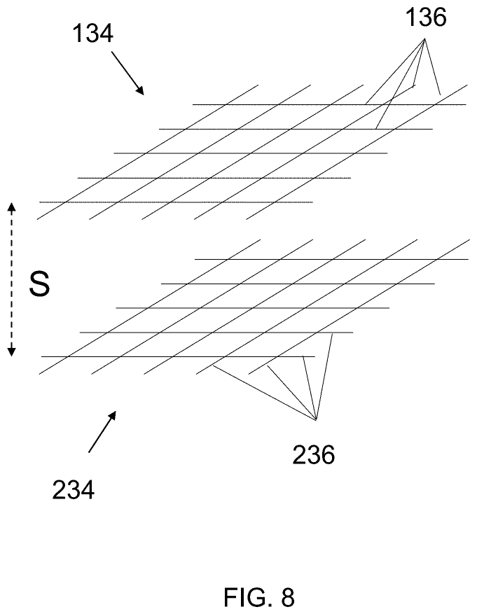

With reference to FIG. 8, in an arrangement, the window comprises a secondary layer comprising a second structure 234 of second metallic wires 236. The secondary layer is separated from the first structure 134 of first metallic wires 136 by a distance denoted ‘S’. Having a secondary layer also arranged to shield RF radiation increases the overall shielding of the window by further attenuating microwave radiation.

While the secondary layer shown in FIG. 8 is of a second structure 234 of second metallic wires 236, the secondary layer could be a different time of transparent shielding layer, e.g. using an ITO layer, etc. Likewise, while a structure in the form of a grid is shown in FIG. 8, this could alternatively be a different structure, e.g. having in-plane curvature.

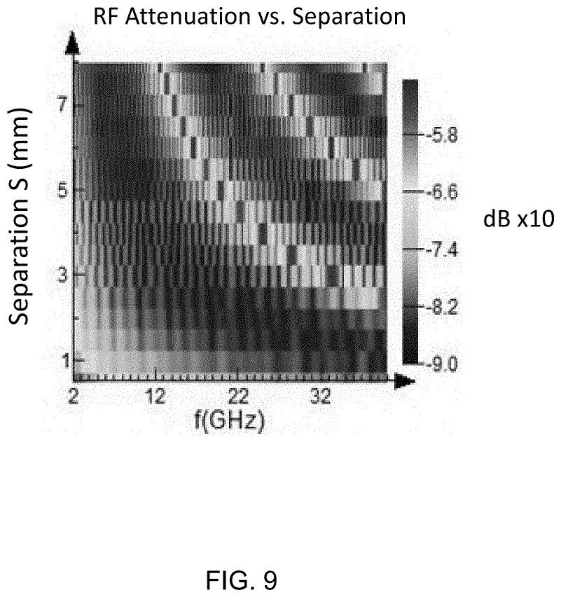

With reference to FIG. 9, having a secondary layer generally provides greater attenuation (coloured blue in the plot of FIG. 9). However, for certain combinations of separation distance S and frequency, there will be a transmission maximum (coloured yellow or red in the plot of FIG. 9). This is a result of the two RF reflective layers (the first structure and the secondary layer) making a form of Fabry-Perot resonators. Accordingly, where a particular separation S meets the Fabry-Perot condition for transmission maximum, there will be a decrease in RF attenuation. For example, for a separation of 6 mm, there are decreases in RF attenuation at approximately 17 GHz and 33 GHz. For 3 mm, there is a decrease in RF attenuation at approximately 33 GHz only. For 2 mm, there is a slight decrease at low frequencies less than 10 GHz. Accordingly, it is advantageous for the separation S to be less than 3 mm, e.g. approximately 2 mm. This maintains the benefit of an additional RF reflective layer but does not result in higher order Fabry-Perot resonances.

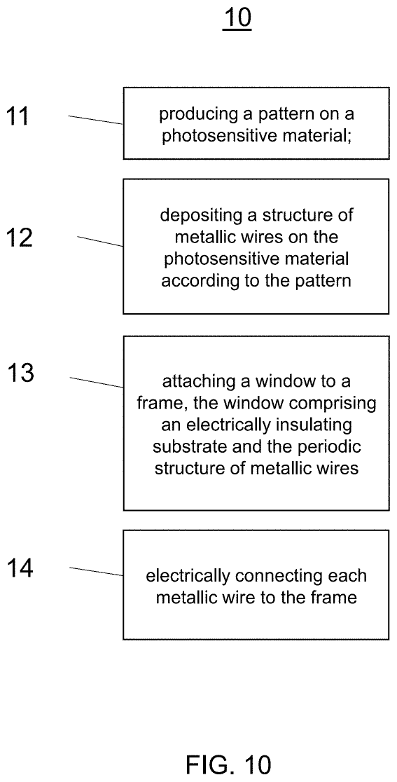

With reference to FIG. 10, a method 10 for manufacturing a screen for shielding RF radiation comprises producing 11 a periodic pattern on a photosensitive material, depositing 12 a structure of metallic wires on the photosensitive material according to the pattern, attaching 13 a window to a frame, the window comprising an electrically insulating substrate and the periodic structure of metallic wires and electrically connecting 14 each metallic wire to the frame. The producing the pattern may be done by applying a mask to the photosensitive material, removing portions of the mask and etching the patterned mask such that troughs are present where portions of the mask were removed. In an example, the producing and depositing may be performed by Rolling Mask Lithography® as described, for example, in U.S. Pat. No. 9,244,356 to Boris Kobrin, et. al, issued Jan. 26, 2016, the entire contents of which are herein incorporated by reference.

The connecting each metallic wire to the frame may entail depositing one or more conductive bridge between the frame and the structure of metallic wires. This may be done as part of the depositing 12 the structure of metallic wires, e.g. the pattern extends onto the frame. As another example, the depositing one or more conductive bridge may be performed subsequently to the depositing 12 of the structure, e.g. using typical metal depositing techniques. As another example, the frame may have one or more conductive protrusions which, when attaching 13 the window to the frame, contact the structure of metallic wires thereby electrically connecting the frame and structure. In any example, the electrical connections between the metallic wires and the frame may be at one or more positions of the structure of metallic wires, e.g. at each corner of the window.

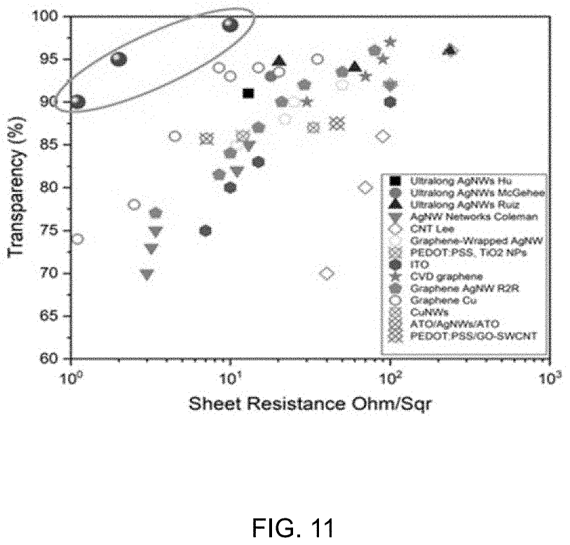

With reference to FIG. 11, a microwave device according to the present disclosure has a window with improved RF shielding and optical properties. A comparison between a substrate with a structure of metallic wires according to the present disclosure, circled points in red, with the other shielding materials is shown in FIG. 11. The present disclosure provides a much lower sheet resistance at lower values (and therefore improved shielding) for a similar level of transparency, or much higher transparency for a similar level of sheet resistance, compared to silver nanowires, ITO, graphene, carbon nanotubes, etc. according to various specifications.

It is to be understood that the above description is intended to be illustrative, and not restrictive. Many other implementations will be apparent to those of skill in the art upon reading and understanding the above description. Although the present disclosure has been described with reference to specific example implementations, it will be recognized that the disclosure is not limited to the implementations described but can be practised with modification and alteration within the scope of the appended claims. Accordingly, the specification and drawings are to be regarded in an illustrative sense rather than a restrictive sense. Although various features of the approach of the present disclosure have been presented separately (e.g., in separate figures), the skilled person will understand that, unless they are presented as mutually exclusive, they may each be combined with any other feature or combination of features of the present disclosure.

1. A microwave device comprising:
a microwave cavity;
a frame defining a perimeter of an opening in the microwave cavity, wherein the frame is conductive and grounded; and
a window spanning the opening, wherein the window is arranged to reflect RF radiation back into the cavity and to shield the outside of the microwave cavity from RF radiation, wherein the window is optically transparent, the window comprising:
an electrically insulating substrate; and
a structure of metallic wires supported by the substrate, wherein each metallic wire of the structure is electrically connected to the frame, wherein the width of each metallic wire is between 100 nanometres and 30 micrometres.

2. The microwave device of claim 1, wherein the structure of metallic wires is periodic.

3. The microwave device of claim 1, wherein the period of the periodic structure is less than 500 micrometres.

4. The microwave device of claim 1, wherein the structure of metallic wires is a rectangular grid of intersecting wires.

5. The microwave device of claim 1, wherein each metallic wire of the structure has in-plane curvature.

6. The microwave device of claim 5, wherein the structure of metallic wires comprises a plurality of wire portions, wherein each wire portion is an arc being approximately a quarter of a circle, wherein each connection between adjacent wire portions is a T-junction.

7. The microwave device of claim 1, wherein the width of one or more metallic wire differs along the length of the metallic wire.

8. The microwave device of claim 1, wherein the total metallized area of the structure of metallic wires is less than 20% of the area of the opening.

9. The microwave device of claim 1, wherein the window further comprises:
a secondary layer in a plane substantially parallel to the structure of metallic wires, wherein the second layer is arranged to reflect RF radiation back into the cavity and to shield the outside of the microwave cavity from RF radiation.

10. The microwave device of claim 9, wherein the secondary layer comprises a second structure of second metallic wires, wherein each second metallic wire of the second structure is electrically connected to the frame, wherein the width of each second metallic wire is between 100 nanometres and 30 micrometres.

11. The microwave device of claim 9, wherein the secondary layer is separated from the first structure, in a direction perpendicular to the plane, by between 0.08 and 0.42 times the effective wavelength of an operating frequency of the microwave device.

12. The microwave device according to claim 1, wherein the thickness of each metallic wire is between 100 nanometres and 30 micrometres.

13. The microwave device according to claim 1, wherein the window has one or more of the following properties:
RF reflectance greater than 99%;
RF absorbance of less than 1%;
RF reflectance greater than 99% and RF absorbance of less than 1%;
RF attenuation greater than 20 dB;
RF attenuation greater than 40 dB;
DC sheet resistance of the structure of metallic wires less than 2 Ohm per square and RF sheet resistance the structure of metallic wires less than 2 Ohm per square;
optical transparency greater than 75%, DC sheet resistance of the structure of metallic wires less than 2 Ohm per square, and RF sheet resistance the structure of metallic wires less than 2 Ohm per square;
DC sheet resistance of the structure of metallic wires less than 5 Ohm per square and RF sheet resistance the structure of metallic wires less than 5 Ohm per square;
optical transparency greater than 90%, DC sheet resistance of the structure of metallic wires less than 5 Ohm per square, and RF sheet resistance the structure of metallic wires less than 5 Ohm per square;
DC sheet resistance of the structure of metallic wires less than 100 Ohm per square and RF sheet resistance the structure of metallic wires less than 100 Ohm per square;
optical transparency greater than 98%, DC sheet resistance of the structure of metallic wires less than 100 Ohm per square, and RF sheet resistance the structure of metallic wires less than 100 Ohm per square;
transmissive optical haze less than 10%;
transmissive optical haze less than 5%; and
transmissive optical haze less than 2%.

14. The microwave device according to claim 1, wherein the microwave cavity includes a door, wherein the door comprises the frame and the window.

15. The microwave device according to claim 1, further comprising:
a source of RF radiation arranged to emit RF radiation at an operating frequency into the microwave cavity, wherein the window is arranged to reflect RF radiation back into the cavity at the first wavelength and to shield the outside of the microwave cavity from RF radiation at the operating frequency.

16. The microwave device according to claim 1, further comprising:
a plurality of frames including the frame, wherein each frame defines a perimeter of a respective opening of the microwave cavity, wherein each frame is conductive and grounded; and
a plurality of windows including the window, wherein each window spans the respective opening of a respective frame, wherein each window comprises:
an electrically insulating substrate; and
a structure of metallic wires supported by the respective substrate, wherein each metallic wire of the structure is electrically connected to the respective frame, wherein the width of each metallic wire is between 100 nanometres and 30 micrometres.

17. The microwave device of claim 16, wherein the plurality of frames collectively covers the majority of the surface area of the microwave cavity.

18. A method of manufacturing a screen for shielding RF radiation, the method comprising:
producing a pattern on a photosensitive material;
depositing a structure of metallic wires on the photosensitive material according to the pattern, wherein the width of each metallic wire is between 100 nanometres and 30 micrometres;
attaching a window to a frame, wherein the frame defines a perimeter of an opening, such that the window spans the opening, wherein the window is optically transparent, wherein the window comprises:
an electrically insulating substrate; and
the periodic structure of metallic wires supported by the substrate; and
electrically connecting each metallic wire to the frame.

19. A screen for shielding RF radiation comprising:
a frame defining a perimeter of an opening, wherein the frame is conductive and grounded; and
a window spanning the opening, wherein the window is arranged to not transmit RF radiation therethrough, wherein the window is optically transparent, the window comprising:
an electrically insulating substrate; and
a structure of metallic wires supported by the substrate, wherein each metallic wire of the structure is electrically connected to the frame, wherein the width of each metallic wire is between 100 nanometres and 30 micrometres.

20. (canceled)

21. A multifunctional microwave metamaterial layer arranged to be reflective and attenuating to microwave radiation and simultaneously transparent to optical radiation, comprising:
an electrically insulating, optically transparent substrate; and
a structured array of metallic wire patterns supported by the substrate, wherein each metallic wire in each pattern of the array is electrically connected to at least one point on the periphery of the layer, wherein the width of each metallic wire is between 100 nanometres and 30 micrometres.

22. The metamaterial layer of claim 21, wherein the DC sheet resistance averaged over any sub-area of the metamaterial layer is less than 2 Ohm per square, and the optical transparency is greater than 75%.

23. The metamaterial layer of claim 21, wherein the DC sheet resistance averaged over any sub-area of the metamaterial layer is less than 5 Ohm per square, and the optical transparency is greater than 90%.

24. The metamaterial layer of claim 21, wherein the DC sheet resistance averaged over any sub-area of the metamaterial layer is less than 100 Ohm per square, and the optical transparency is greater than 98%.

25. The metamaterial layer of claim 21, wherein the layer is arranged to have transmissive optical haze less than either of the 10%, 5%, 2%.
